(19) United States
(12) Patent Application Publication
(10) Pub. No.: US 2004/0248430 A1
(43) Pub. Date: Dec. 9, 2004

(54) Wafer cooling chuck with direct coupled peltier unit

(76) Inventors: Rennie Barber, Gresham, OR (US); Mark Mayeda, Portland, OR (US)

Correspondence Address: Leo J. Peters, LSI Logic Corporation, MS D-106, 1551 McCarthy Blvd., Milpitas, CA, 95035, US

(21) Appl. No.: 10/457,893

(22) Filed: Jun. 9, 2003

(51) Int. Cl. B24B 49/00; H01L 21/324; H01L 21/64; H01L 21/477; H01L 21/00; B24B 51/00; H01L 21/26; C23C 16/00; H01L 21/42

(52) U.S. Cl. 438/795; 438/800; 118/719; 118/733; 451/7

(57) ABSTRACT

A device for transferring an object between manufacturing steps includes a transfer surface for receiving an object having an initial temperature from a first manufacturing step, for transporting the object from the first manufacturing step to another manufacturing step, and for transferring the object having a final temperature from the transfer surface to the other manufacturing step; and at least one Peltier unit coupled to the transfer surface for effecting a temperature change of the object from the initial temperature to the final temperature at a controlled rate.

### BACKGROUND OF THE INVENTION

1. Field of the Invention

The present invention relates generally to the manufacture of integrated circuits. More specifically, but without limitation thereto, the present invention relates to the handling of silicon wafers between steps performed in the manufacture of integrated circuits.

2. Description of Related Art

Integrated circuits are typically manufactured from silicon wafers having a diameter of several hundred millimeters. Some of the steps used in the processing of these silicon wafers result in heating the silicon wafers to a temperature too high to allow the wafers to be loaded into wafer cassettes that are typically made of a plastic material. The silicon wafers must therefore be cooled sufficiently prior to loading into the wafer cassettes to avoid problems such as thermal distortion of the wafer cassettes and bonding of the wafers to the wafer cassettes.

In previous approaches to cooling wafers before loading them into wafer cassettes, each wafer is loaded onto a cooling chuck. A cooling chuck is a temporary metal resting area that allows the wafer to cool sufficiently before loading the wafer into a wafer cassette.

### SUMMARY OF THE INVENTION

In one aspect of the present invention, a device for transferring an object from one manufacturing step to another includes a transfer surface for receiving an object having an initial temperature from a first manufacturing step, for transporting the object from the first manufacturing step to another manufacturing step, and for transferring the object having a final temperature from the transfer surface to the other manufacturing step; and at least one Peltier unit coupled to the transfer surface for effecting a temperature change of the object from the initial temperature to the final temperature at a controlled rate.

In another aspect of the present invention, a device for handling an object between manufacturing steps includes a platen of a wafer cooling chuck wherein the platen has a transfer surface for receiving a semiconductor wafer and at least one Peltier unit coupled to the platen for effecting a temperature change of the semiconductor wafer at a controlled rate.

In a further aspect of the present invention, a device for handling an object between manufacturing steps includes a robot end effector having a transfer surface for receiving a semiconductor wafer and at least one Peltier unit coupled to the robot end effector for effecting a temperature change of a semiconductor wafer at a controlled rate.

In yet another aspect of the present invention, a method of handling an object between manufacturing steps includes steps of:

(a) receiving an object having an initial temperature on a transfer surface from a first manufacturing step;

(b) effecting a temperature change of the object at a controlled rate from the initial temperature to a final temperature by at least one Peltier unit coupled to the transfer surface;

(c) transporting the object on the transfer surface to another manufacturing step; and

(d) transferring the object from the transfer surface to the other manufacturing step after the object reaches the final temperature.

### DESCRIPTION OF THE SEVERAL VIEWS OF THE DRAWINGS

The present invention is illustrated by way of example and not limitation in the accompanying figures, in which like references indicate similar elements throughout the several views of the drawings, and in which:

FIGS. 1A and 1B illustrate top and side views of a cooling chuck of the prior art;

FIGS. 2A and 2B illustrate top and side views of a cooling chuck according to an embodiment of the present invention;

FIG. 3 illustrates a diagram of a Peltier unit of the prior art;

FIG. 4 illustrates a block diagram of an exemplary temperature controller that may be used to control the wafer cooling rate of the cooling chuck in FIGS. 2A and 2B;

FIGS. 5A and 5B illustrate top and side views of a robot end effector according to an embodiment of the present invention; and

FIG. 6 illustrates a flow chart for a method of controlling a temperature change of an object according to an embodiment of the present invention.

Elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION OF THE ILLUSTRATED EMBODIMENTS

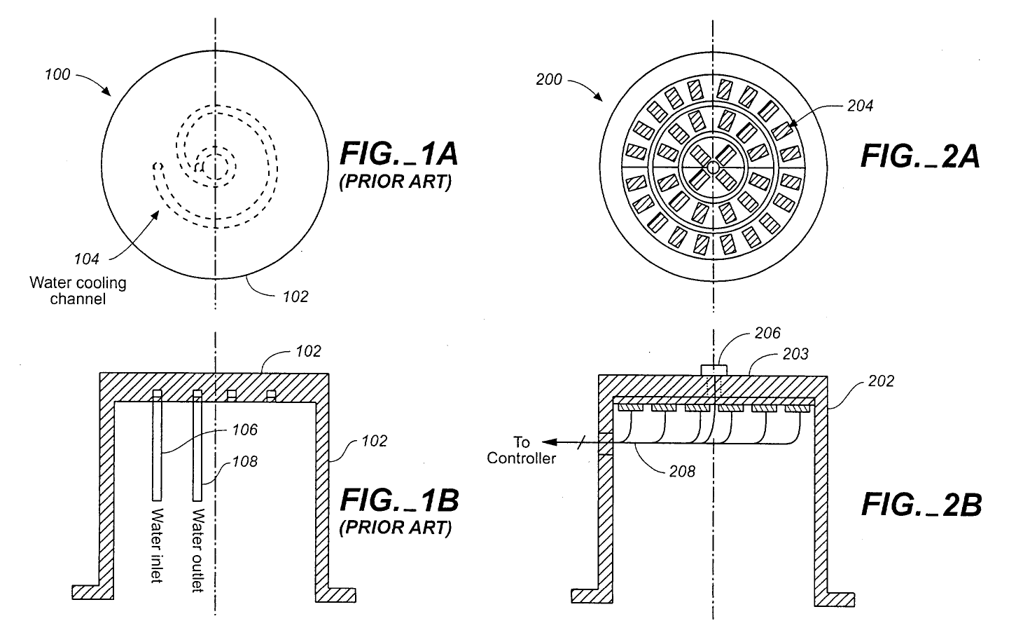

FIGS. 1A and 1B illustrate top and side views of a cooling chuck 100 of the prior art. Shown in FIGS. 1A and 1B are a platen 102, a coolant channel 104, a coolant inlet 106, and a coolant outlet 108.

The platen 102 is typically made of a heat conducting metal, for example, aluminum. The coolant channel 104 is generally machined into the backside of the platen 102. The coolant (not shown) is typically a liquid or a gas that is introduced from a chilled coolant reservoir (not shown) by way of the coolant inlet 106. The coolant is circulated through the coolant channel 104 and out through the coolant outlet 108 back to the coolant reservoir. The circulation of the coolant through the coolant channel 104 conducts heat from a semiconductor wafer (not shown) placed on top of the platen 102.

A disadvantage of the cooling chuck 100 in FIGS. 1A and 1B is the amount of time required to cool a semiconductor wafer placed on the cooling chuck, typically within a range of one to two minutes, to a safe temperature for loading into a wafer cassette, preferably less than 50 degrees Centigrade. The cooling rate of the semiconductor wafer is determined by the properties of the cooling chuck 100 and generally may not be conveniently selected to minimize the time required to reach a desired final temperature. The cooling time may be decreased by increasing the difference in temperature between the platen 102 and the semiconductor wafer, however, too great a difference in temperature may result in damage to the semiconductor wafer due to thermal shock. The temperature difference beyond which thermal damage to the semiconductor wafer is likely is referred to herein as the thermal shock threshold. To avoid thermal shock, the temperature of the coolant may be maintained at an initial temperature when the semiconductor wafer is placed on the cooling chuck 100 that does not exceed the thermal shock threshold. The temperature of the coolant may then be cooled to a lower temperature as the semiconductor wafer cools while ensuring that the temperature difference between the cooling chuck 100 and the semiconductor wafer does not exceed the thermal shock threshold. A disadvantage of this approach is that heat must first be transferred from the coolant into the coolant reservoir outside the cooling chuck 100, then heat is transferred from the platen 102 into the coolant. This two-step heat transfer process complicates the process of effecting a temperature change of the semiconductor wafer at a controlled rate.

The present invention advantageously avoids the problems associated with the two-step process of controlling the rate of temperature change in the semiconductor wafer and the cooling chuck 100, and further provides a method for effecting a rapid temperature change of the semiconductor wafer at a controlled rate that does not exceed the thermal shock threshold or other limitation that may be imposed on the rate of temperature change of the semiconductor wafer.

In one aspect of the present invention, a device for transferring an object from one manufacturing step to another includes a transfer surface for receiving an object having an initial temperature from a first manufacturing step, for transporting the object from the first manufacturing step to another manufacturing step, and for transferring the object from the transfer surface to the other manufacturing step; and at least one Peltier unit coupled to the transfer surface for effecting a temperature change of the object from the initial temperature to a final temperature at a controlled rate.

FIGS. 2A and 2B illustrate top and side views of a cooling chuck 200 according to an embodiment of the present invention. Shown in FIGS. 2A and 2B are a platen 202, a transfer surface 203, Peltier units 204, a thermocouple 206, and signal wires 208.

The platen 202 may be made an a manner identical to that of the platen 102 in FIG. 1, except that no cooling channel is necessary. Instead of a cooling channel, the Peltier units 204 may be fastened to the back of the platen 202 under the transfer surface 203 according to well-known techniques, for example, by an adhesive, screws or clamps. A thermal grease or compound may be applied between the Peltier units 204 and the platen 202 to improve thermal coupling between the Peltier units 204 and the platen 202. The Peltier units 204 are advantageously coupled to the platen 202 to control the temperature of the platen 202 directly, rather than indirectly through a coolant as in the example of FIG. 1.

The thermocouple 206 is preferably mounted near the transfer surface 203 of the platen 202 according to well-known techniques to monitor the temperature of the platen 202. Alternatively, one or more thermocouples may be mounted at various locations on or near the platen 202 according to well-known techniques to monitor the temperature of the platen 202 and that of the semiconductor wafer when it is placed on the transfer surface 203.

The signal wires 208 from the thermocouple 206 and the Peltier units 204 are routed to a controller that controls the heating or cooling rate and the setpoint temperature.

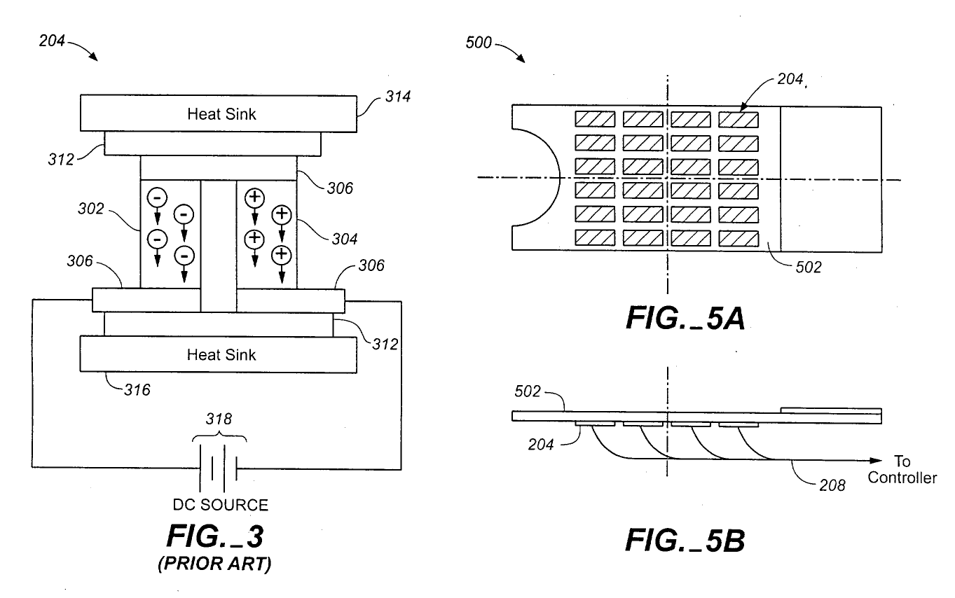

FIG. 3 illustrates a diagram of a Peltier unit 204 of the prior art. Shown in FIG. 3 are an N-type semiconductor pellet 302, a P-type semiconductor pellet 304, connecting tabs 306, a positive lead 308, a negative lead 310, insulating substrates 312, heat sinks 314 and 316, and a power source 318.

The N-type semiconductor pellet 302 and the P-type semiconductor pellet 304 are typically made of, for example, bismuth telluride. The N-type semiconductor pellet 302 and the P-type semiconductor pellet 304 are connected electrically in series by the electrically conductive connecting tabs 306 to the positive lead 308 and negative lead 310, which are connected to the power source 318. The insulating substrates 312 are typically made of a metallized ceramic to provide electrical insulation and high thermal conductivity between the connecting tabs 306 and the heat sinks 314 and 316.

When electrical current flows between the positive lead 308 and the negative lead 310 from the power source 318, heat is transferred from the heat sink 314 to the heat sink 316. As a result, the temperature of the heat sink 314 falls, and the temperature of the heat sink 316 rises.

By coupling an array of Peltier units 204 directly to the platen 202 under the transfer surface 203 as shown in FIGS. 2A and 2B so that heat is conducted away from the platen 202, the temperature of the platen 102 may likewise be controlled directly instead of by the two-step method described above with regard to FIGS. 1A and 1B.

The specific arrangement of the Peltier units 204 on the back of the platen 202 shown in FIGS. 2A and 2B is for purposes of illustration only, and other arrangements of one or more Peltier units 204 at various locations on the platen 202 may be used to practice the present invention within the scope of the appended claims. Alternatively, the heat sinks 316 of the Peltier units 204 to which heat is transferred (the hot side) may be coupled according to well-known techniques to a larger heat sink or to a heat exchanger (not shown) to increase the efficiency of the Peltier units 204.

A distinctive feature of the present invention is the use of Peltier units 204 to transfer heat from the platen 202 of the cooling chuck 200. Another distinctive feature is that heat may be transferred directly from the platen 202 to the Peltier units 204 at a selectable cooling rate that may be controlled by varying the current supplied by the power source 318 to the Peltier units 204. As a result, temperature changes may be effected more quickly than by previous methods that require a coolant.

One or more thermocouples 206 may be attached, for example, to the Peltier units 204 and to the platen 202 according to well-known techniques to monitor the temperature of the platen 202 and the temperature difference between the wafer and the platen 202. The temperature difference between the wafer and the platen 202 may be also be estimated according to well-known techniques from the known thermal conductivity of the wafer, the platen 202, and the heat sinks 314 and 316 of the Peltier units 204 as a function of the initial temperature of the wafer and the power supplied to the Peltier units 204.

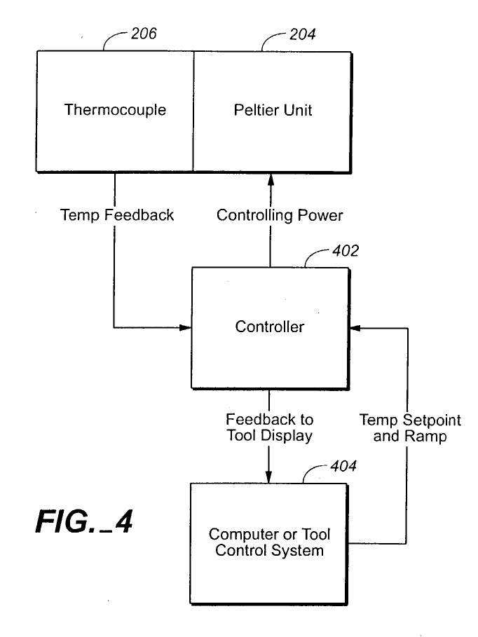

FIG. 4 illustrates a block diagram of an exemplary temperature controller 400 that may be used to control the wafer cooling rate of the cooling chuck 200 in FIGS. 2A and 2B. Shown in FIG. 4 are a thermocouple 206, a Peltier unit 204, a power controller 402, and a feedback controller 404.

The thermocouple 206 may be attached, for example, to the platen 202 as shown in FIG. 2 to monitor the temperature of the surface of the platen 202 facing the wafer. The power controller 402 receives the output of the thermocouple 206 and relays the temperature value measured by the thermocouple 206 to the feedback controller 404. The feedback controller 404 compares the temperature value from the thermocouple 206, for example, to a table of temperature values, and retrieves a corresponding temperature setpoint and ramp value from the table. The setpoint temperature is an intermediate or final desired temperature of the platen 202. The ramp value is a value of electrical current that is representative of the selected rate of change from the current temperature to the intermediate or final temperature. The temperature setpoint and ramp values are transmitted from the feedback controller 404 to the power controller 402.

The power controller supplies a current to the Peltier unit 204 to change the temperature of the platen 202 to the setpoint temperature at the selected ramp rate so that the temperature of the platen 202 is reduced as quickly as possible without exceeding a predetermined thermal shock threshold of the semiconductor wafer. Other methods and devices may be employed to control the temperature of the platen 202 by the Peltier units 204 according to well-known techniques.

Alternatively, heated wafers may be cooled while being transported from a deposition chamber or other heated surface to a wafer cassette by wafer handling robots. In this example, the Peltier units are mounted on a wafer handling robot “arm”, called a robot end effector.

In another aspect of the present invention, a device for transferring an object between manufacturing steps includes a robot end effector and at least one Peltier unit coupled to the robot end effector for effecting a temperature change of an object at a controlled rate.

FIGS. 5A and 5B illustrate top and side views of a robot end effector 500 according to an embodiment of the present invention. Shown in FIG. 5 are a transfer surface 502, Peltier units 204, and signal wires 208.

The robot end effector 500 may be made in the same manner as that used for wafer handling robots widely used in the semiconductor processing industry. One or more Peltier units 204 may be mounted directly under the transfer surface 502, for example, by adhesive, screws or clamps according to well-known techniques as described above with regard to the cooling chuck 200 in FIGS. 2A and 2B. The Peltier units 204 may also be controlled, for example, using the temperature control device of FIG. 4 connected to the signal wires 208. When the semiconductor wafer is received from the first manufacturing step by the transfer surface 502, the temperature of the wafer may be changed from an initial temperature resulting from the first manufacturing step to a desired final temperature at which the semiconductor wafer is to be transferred to the other manufacturing step at a rate controlled by the current supplied to the Peltier units 204.

Other objects besides semiconductor wafers and other manufacturing steps besides those used in semiconductor manufacturing may be used to practice the invention within the scope of the appended claims. For example, newly formed glass objects may be transported safely from an oven to a packing carton using a robot end effector cooled by Peltier units.

Alternatively, in applications where it is desirable to control the heating rate of an object subject to thermal shock during handling between steps in a manufacturing process, the orientation of the heat sinks on the Peltier units 204 may be reversed on the robot end effector 500 in FIGS. 5A and 5B or on the platen 202 in FIGS. 2A and 2B so that heat is transferred into the object instead of away from it. The temperature control device of FIG. 4 used to control the cooling rate of an object during handling between manufacturing steps may be also used to control the heating rate of an object, for example, by supplying the appropriate values to the table of temperatures, temperature setpoints, and ramp values according to well-known techniques.

In a general sense, a temperature change may be effected in an object according to various embodiments of the present invention by transferring an object having an initial temperature from one step of a first manufacturing step to a transfer surface. In the illustrated examples, the object is a semiconductor wafer. The first manufacturing step may be, for example, a chemical vapor or plasma deposition chamber. The transfer surface may be, for example, a platen of a wafer cooling chuck or a robot end effector of a wafer handling robot.

The temperature change of the object from the initial temperature resulting from the first manufacturing step to the final temperature at which the object is to be transferred to the other manufacturing step is effected by at least one Peltier unit coupled to the transfer surface.

The object is transported on the transfer surface to the other manufacturing process, for example, inserting the object into a wafer cassette. After the object reaches the selected final temperature, the object is transferred from the transfer surface to the other manufacturing process.

In another aspect of the present invention, a method of controlling a temperature change of an object includes steps of:

(a) receiving an object having an initial temperature on a transfer surface from a first manufacturing step;

(b) effecting a temperature change of the object at a controlled rate from the initial temperature to a final temperature by at least one Peltier unit coupled to the transfer surface;

(c) transporting the object on the transfer surface to another manufacturing step; and

(d) transferring the object from the transfer surface to the other manufacturing step after the object reaches the final temperature.

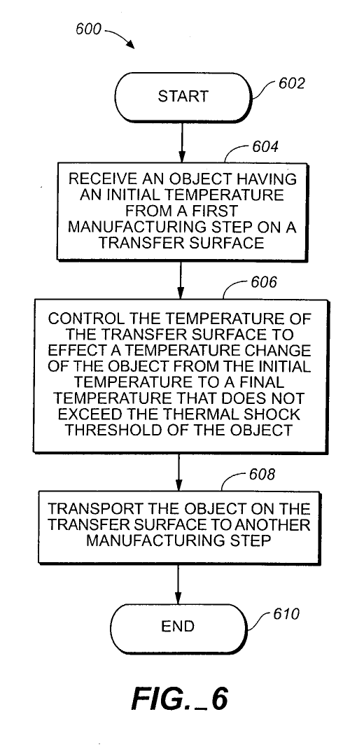

FIG. 6 illustrates a flow chart 600 for a method of controlling a temperature change of an object according to an embodiment of the present invention.

Step 602 is the entry point of the flow chart 600.

In step 604, an object having an initial temperature is received from a first manufacturing step. For example, the transfer surface may be a platen of a cooling chuck or a robot end effector of a wafer handling robot as described above, the object may be a semiconductor wafer, and the first manufacturing step may be a chemical vapor or plasma deposition chamber.

In the context of the present invention, a manufacturing step includes the apparatus used to perform the manufacturing step and the location of the apparatus. By including the apparatus and the location of the apparatus associated with a manufacturing step in the definition of the manufacturing step, the various embodiments of the present invention may be more conveniently expressed. For example, some processing tools may include multiple process chambers for performing the manufacturing steps, and the multiple process chambers are connected by a common wafer transport module. The wafer may be cooled on a transfer surface in the transport module before being transferred to another process chamber.

In step 606, the temperature of the transfer surface is controlled to effect a temperature change of the object from the initial temperature to a final temperature within a selected period of time or at a controlled rate, for example, to maintain a temperature difference between the object and the transfer surface that does not exceed a thermal shock threshold of the object.

In step 608, the object is transported on the transfer surface, for example, the robot end effector, to another manufacturing step, for example, a wafer cassette.

The transportation of the object to the other manufacturing step may include, for example, moving an object to a stationary manufacturing step as exemplified by the robot end effector 500 in FIG. 5, moving a manufacturing step to a stationary object as exemplified by bringing a wafer cassette to the cooling chuck 200 of FIG. 2, or moving both the manufacturing step and the object together. The object may be transported concurrently while effecting the change of temperature of the object to the desired final temperature, or the temperature change may be effected before transporting the object, or the temperature change may be effected after transporting the object.

In step 610, the object is transferred from the transfer surface after reaching the final temperature to the other manufacturing step.

Step 612 is the exit point of the flow chart 600.

Although the method of the present invention illustrated by the flowchart description above is described and shown with reference to specific steps performed in a specific order, these steps may be combined, sub-divided, or reordered without departing from the scope of the claims. Unless specifically indicated herein, the order and grouping of steps is not a limitation of the present invention.

While the invention herein disclosed has been described by means of specific embodiments and applications thereof, other modifications, variations, and arrangements of the present invention may be made in accordance with the above teachings other than as specifically described to practice the invention within the spirit and scope defined by the following claims.

What is claimed is:

1. A device for handling an object between manufacturing steps comprising:
a transfer surface for receiving an object having an initial temperature from a first manufacturing step, for transporting the object from the first manufacturing step to another manufacturing step, and for transferring the object having a final temperature from the transfer surface to the other manufacturing step; and
at least one Peltier unit coupled to the transfer surface for effecting a temperature change of the object from the initial temperature to the final temperature at a controlled rate.

2. The device of claim 1 wherein the object is a semiconductor wafer and the transfer surface is a platen of a wafer cooling chuck.

3. The device of claim 1 wherein the object is a semiconductor wafer and the transfer surface is a robot end effector.

4. The device of claim 1 wherein the at least one Peltier unit is coupled to the transfer surface for cooling the object from the initial temperature to the final temperature.

5. The device of claim 1 wherein the at least one Peltier unit is coupled to the transfer surface for heating the object from the initial temperature to the final temperature.

6. The device of claim 1 further comprising a thermocouple coupled to the transfer surface for measuring a temperature of the transfer surface.

7. The device of claim 1 further comprising a thermocouple coupled to the object for measuring a temperature of the object.

8. The device of claim 1 further comprising a temperature controller coupled to the at least one Peltier unit for supplying an electrical current to the at least one Peltier unit to control the rate of the temperature change of the object.

9. The device of claim 1 wherein the controlled rate of the temperature change of the object is selected to avoid exceeding a thermal shock threshold of the object.

10. A device for handling an object between manufacturing steps comprising:
a robot end effector having a transfer surface for receiving a semiconductor wafer; and
at least one Peltier unit coupled to the robot end effector for effecting a temperature change of the semiconductor wafer at a controlled rate.

11. The device of claim 10 further comprising a temperature controller coupled to the at least one Peltier unit for supplying an electrical current to the at least one Peltier unit to control the rate of the temperature change of the semiconductor wafer.

12. The device of claim 10 further comprising a thermocouple coupled to the robot end effector.

13. A device for handling an object between manufacturing steps comprising:
a platen of a wafer cooling chuck having a transfer surface for receiving a semiconductor wafer; and
at least one Peltier unit coupled to the platen for effecting a temperature change of the semiconductor wafer at a controlled rate.

14. The device of claim 13 further comprising a thermocouple coupled to the platen.

15. The device of claim 13 further comprising a temperature controller coupled to the at least one Peltier unit for supplying an electrical current to the at least one Peltier unit to control the rate of the temperature change of the semiconductor wafer.

16. A method of handling an object between manufacturing steps comprising steps of:
(a) receiving an object having an initial temperature on a transfer surface from a first manufacturing step;
(b) effecting a temperature change of the object at a controlled rate from the initial temperature to a final temperature by at least one Peltier unit coupled to the transfer surface;
(c) transporting the object on the transfer surface to another manufacturing step; and
(d) transferring the object from the transfer surface to the other manufacturing step after the object reaches the final temperature.

17. The method of claim 16 further comprising coupling an electrical current to the at least one Peltier unit to control the rate of the temperature change of the object.
